(19) United States
(12) Patent Application Publication
(10) Pub. No.: US 2024/0297628 A1
(43) Pub. Date: Sep. 5, 2024

(54) RF POWER AMPLIFICATION APPARATUS

(71) Applicant: Skyworks Solutions, Inc., Irvine, CA (US)

(72) Inventors: Neal J. Tuffy, Great Shelford (GB); Martin John O’Flaherty, Bishop’s Stortford (GB); Tomas J. Tansley, Andover, MA (US); Valter Karavanic, Nashua, NH (US)

(21) Appl. No.: 18/592,918

(22) Filed: Mar. 1, 2024

Related U.S. Application Data
(60) Provisional application No. 63/449,669, filed on Mar. 3, 2023.

(51) Int. Cl. H03G 3/30; H03F 3/24; H04W 52/52; H04W 84/12

(52) U.S. Cl. CPC H03G 3/3042; H03F 3/245; H04W 52/52; H03F 2200/451; H03G 2201/103; H03G 2201/307; H04W 84/12

(57) ABSTRACT

A power amplifier includes a power amplifier stage configured to amplify a signal received from an attenuator or from a variable gain amplifier. An open loop transient gain compensation circuit compensates a transient turn-on gain variation of the power amplifier stage with a transient compensation current added to a bias current supplied to the attenuator or supplied to the variable gain amplifier.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

Ever-evolving WiFi standards continue to impose increasingly strict linearity demands on radio frequency, RF, wireless transmitters. RF power amplifiers (PA) are key components in a transmitter chain that dominates the linearity of the transmitted signal.

Error vector magnitude (EVM) forms a common measure for power amplify linearity. A degradation in the error vector magnitude, EFM is usually a result of impairments such as raw power amplifier non-linearity (AM/AM and AM-PM), noise or bandwidth limitations. Additionally, for dynamic error vector magnitude (DEVM) under bursted WiFi signal excitation there are additional sources of linearity degradation in the form of gain drift or droop and transient turn-on gain variation. A gain drift of gain droop may arise from power device heating over the length of a long burst, i.e. a burst lasting longer than 1 millisecond.

Transient turn-on gain variation has until now received little attention even though it can be a source of major error vector magnitude (EVM) degradation, in particular if the gain transient does perturb both the preamble and the payload.

### SUMMARY

In some aspects, the techniques described herein relate to a power amplification apparatus including: a power amplifier stage (PA) configured to amplify a signal received from an attenuator or from a variable gain amplifier (VGA) of the power amplification apparatus with an amplifier gain (G); and an open loop transient gain compensation circuit configured to compensate a transient turn-on gain variation of the power amplifier stage (PA) with a transient compensation current (Icomp) added to a bias current (Ibias) supplied to the attenuator or supplied to the variable gain amplifier (VGA).

In some aspects, the techniques described herein relate to a power amplification apparatus wherein the open loop transient gain compensation circuit includes a transient compensation current generator configured to generate the transient compensation current (Icomp).

In some aspects, the techniques described herein relate to a power amplification apparatus wherein the transient compensation current generator of the open loop transient gain compensation circuit includes a memory circuit with a number of registers and a bank of capacitors controlled according to settings of at least one register of the memory circuit.

In some aspects, the techniques described herein relate to a power amplification apparatus wherein the transient compensation current generator of the open loop transient gain compensation circuit is adapted to generate a transient compensation current (Icomp) with a predefined RC-time constant.

In some aspects, the techniques described herein relate to a power amplification apparatus wherein a current amplitude and a RC-time constant of the transient compensation current (Icomp) are programmable via an integrated controller of the power amplification apparatus.

In some aspects, the techniques described herein relate to a power amplification apparatus wherein the memory circuit includes a set of registers having settings adapted to select a transient compensation current (Icomp) with an associated RC-time constant to be added to the bias current (Ibias) depending on an operation mode selected from a number of operation modes.

In some aspects, the techniques described herein relate to a power amplification apparatus wherein the operation mode includes a WiFi power mode.

In some aspects, the techniques described herein relate to a power amplification apparatus wherein the power amplifier stage (PA) and the open loop transient gain compensation circuit are implemented on a power amplifier die.

In some aspects, the techniques described herein relate to a power amplification apparatus wherein an attenuation of the attenuator is modified by an attenuation bias current boosted by the transient compensation current (Icomp) generated by said transient compensation current generator during a transmission burst of the power amplification apparatus.

In some aspects, the techniques described herein relate to a power amplification apparatus wherein the transmission burst includes a preamble for setting a level of modulation followed by a payload for data transmission.

In some aspects, the techniques described herein relate to a power amplification apparatus wherein the open loop transient gain compensation circuit is adapted to compensate the transient turn-on gain variation of the power amplifier stage (PA) with the transient compensation current (Icomp) within an initial first millisecond of the transmission burst.

In some aspects, the techniques described herein relate to a wireless communication device including: an antenna configured to transmit an amplified radio frequency signal; and a power amplification apparatus configured to provide the amplified radio frequency signal to the antenna, the power amplification apparatus including a power amplifier stage (PA) adapted to amplify a signal received from an attenuator or received from a variable gain amplifier (VGA) of the power amplification apparatus with an amplifier gain (G), and an open loop transient gain compensation circuit configured to compensate a transient turn-on gain variation of the power amplifier stage (PA) with a transient compensation current (Icomp) added to a bias current (Ibias) supplied to the attenuator or supplied to the variable gain amplifier (VGA).

In some aspects, the techniques described herein relate to a wireless communication device wherein the open loop transient gain compensation circuit includes a transient compensation current generator configured to generate the transient compensation current (Icomp).

In some aspects, the techniques described herein relate to a wireless communication device wherein the transient compensation current generator of the open loop transient gain compensation circuit includes a memory circuit with a number of registers and a bank of capacitors controlled according to settings of at least one register of the memory circuit.

In some aspects, the techniques described herein relate to a wireless communication device wherein the transient compensation current generator of the open loop transient gain compensation circuit is configured to generate a transient compensation current (Icomp) with a predefined RC-time constant.

In some aspects, the techniques described herein relate to a wireless communication device wherein a current amplitude and the RC-time constant of the transient compensation current (Icomp) are programmable via an integrated controller of the power amplification apparatus.

In some aspects, the techniques described herein relate to a wireless communication device wherein the memory circuit includes a set of registers having settings adapted to select a transient compensation current (Icomp) with an associated RC-time constant to be added to the bias current (Ibias) depending on an operation mode selected from a number of operation modes.

In some aspects, the techniques described herein relate to a wireless communication device wherein the operation mode includes a WiFi power mode.

In some aspects, the techniques described herein relate to a wireless communication device wherein the power amplifier stage (PA) and the open loop transient gain compensation circuit are implemented on a power amplifier die.

In some aspects, the techniques described herein relate to a wireless communication device wherein an attenuation of the attenuator is modified by an attenuation bias current boosted by the transient compensation current (Icomp) generated by the transient compensation current generator during a transmission burst of the power amplification apparatus.

In some aspects, the techniques described herein relate to a wireless communication device wherein the transmission burst includes a preamble for setting a level of modulation followed by a payload for data transmission.

In some aspects, the techniques described herein relate to a wireless communication device wherein the open loop transient gain compensation circuit is configured to compensate the transient turn-on gain variation of the power amplifier stage (PA) with the transient compensation current (Icomp) within an initial first millisecond of the transmission burst.

In some aspects, the techniques described herein relate to a method of compensating a transient turn-on gain variation of a power amplifier stage used for amplifying a signal received from an attenuator or from a variable gain amplifier (VGA), the method including: generating a transient compensation current (Icomp) when turning-on the power amplifier stage (PA); and adding the generated transient compensation current (Icomp) to a bias current (Ibias) supplied to the attenuator to modify its attenuation or supplied to the variable gain amplifier (VGA) to modify its gain.

In some aspects, the techniques described herein relate to a method wherein the transient turn-on gain variation of the power amplifier stage (PA) is compensated by the generated transient compensation current (Icomp) within an initial first millisecond of a transmission burst.

In some aspects, the techniques described herein relate to a method wherein the transmission burst includes a preamble used for setting a level of modulation followed by a payload used for data transmission.

### BRIEF DESCRIPTION OF THE DRAWINGS

FIG. 1 shows a schematic block diagram of a possible exemplary embodiment of a power amplification apparatus according to a first aspect;

FIG. 2 shows a further schematic block diagram illustrating a further possible exemplary embodiment of a power amplification apparatus according to the first aspect;

FIG. 3 shows a flowchart for illustrating the possible exemplary embodiment of a method for compensating a transient turn-on gain variation of a power amplifier stage according to a further aspect;

FIG. 4 shows a schematic diagram for illustrating the operation of a power amplification apparatus;

FIG. 5 shows a schematic block diagram for illustrating a further possible exemplary embodiment of a power amplification apparatus according to the first aspect;

FIG. 6 illustrates a possible exemplary implementation of an open loop gain compensation circuit;

FIGS. 7 to 20 are signal diagrams for illustrating the operation for power amplification apparatus; and

FIG. 21 shows a schematic diagram for illustrating an exemplary electronic system which includes a power amplification apparatus according to the first aspect;

FIG. 22 shows a block diagram of a wireless communication device according to a further aspect.

### DETAILED DESCRIPTION OF EMBODIMENTS

In the following a detailed description of certain embodiments presents various descriptions of specific embodiments. However, the innovations described herein can be embodied in a multiple of different ways, for example, as defined and covered by the claims. In this description, references made to the drawings with like reference numerals can indicate identical or functionally similar elements. It should be understood that elements illustrated in the figures are not necessarily drawn to scale. Moreover it will be understood that certain embodiments can include more elements than illustrated in the drawing and/or in subset of elements illustrated in a drawing. Further, some embodiments can incorporate any suitable combination or features from two or more drawings.

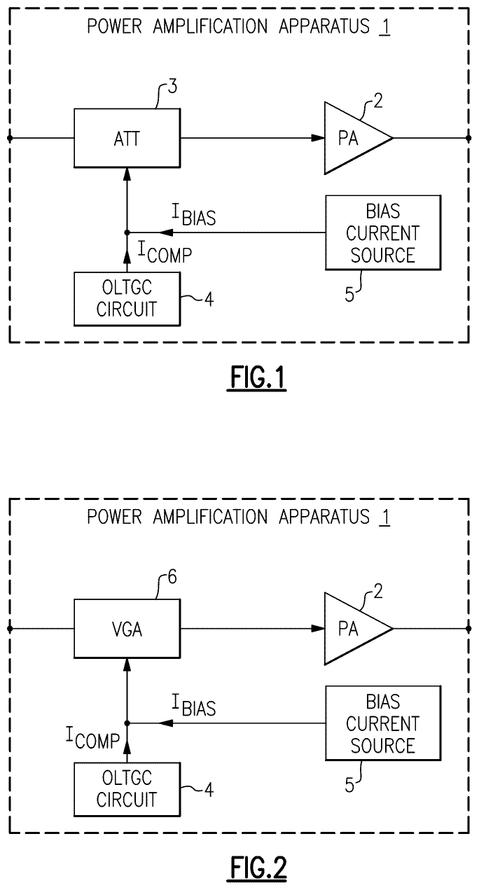

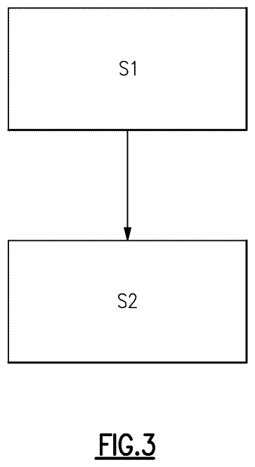

FIGS. 1 and 2 illustrate two exemplary embodiments of a power amplification apparatus 1 according to the first aspect. As can be seen in FIG. 1 the power amplification apparatus 1 comprises in the illustrated embodiment a power amplifier stage 2 which is adapted to amplify a signal received from an attenuator 3 of the power amplification apparatus 1 with an amplifier gain G. The signal amplified by the power amplifier stage comprises a radio frequency, RF, signal. The power amplification apparatus 1 as illustrated in the embodiment of FIG. 1 further comprises an open loop transient gain compensation, OLTGC, circuit 4. The open loop transient gain compensation, OLTGC, circuit 4 is adapted to compensate a transient turn-on gain variation of the power amplifier stage 2 with a transient compensation current Icomp added to a bias current Ibias supplied to said attenuator 3 by a bias current source 5 as illustrated in FIG. 1.

FIG. 2 shows a further possible embodiment of the power amplification apparatus 1 according to the first aspect. In the embodiment illustrated in FIG. 2, power amplification apparatus 1 comprises a power amplifier stage 2 adapted to amplify a signal, in particular an RF signal received from a variable gain amplifier, VGA, 6 of said power amplification apparatus 1 with an amplifier gain G. The power amplification apparatus 1 comprises in the illustrated embodiment of FIG. 2 also an open loop transient gain compensation, OLTGC, circuit 4 adapted to compensate a transient turn-on gain variation of the power amplifier stage 2 with a transient compensation current Icomp added to a bias current (Ibias) supplied to said variable gain amplifier 6 by a bias current source 5.

In a possible embodiment, the open loop transient gain compensation, OLTGC, circuit 4 can comprise a transient compensation current generator adapted to generate the transient compensation current Icomp supplied to the attenuator, ATT, 3 as illustrated in FIG. 1 or supplied to the variable gain amplifier, VGA, 6 as illustrated in FIG. 2. A transient compensation current generator of the open loop transient gain compensation circuit 4 comprises in a possible implementation a bank of capacitors controlled according to settings of at least one register of a memory circuit of said open loop transient gain compensation circuit 4.

The transient compensation current generator of the open loop transient gain compensation circuit 4 is adapted to generate a transient compensation current Icomp with a predefined RC-time constant. In a possible embodiment a current amplitude and an RC-time constant of the transient compensation current Icomp can be programmable via an integrated controller of the power amplification apparatus 1. In a possible implementation, the memory circuit may comprise a set of registers having settings adapted to select a transient compensation current Icomp with an associated RC-time constant to be added to the bias current Ibias depending on an operation mode selected from a number of operation modes. Operation modes may comprise one or more WiFi power modes.

The power amplifier stage 2 of the power amplification apparatus 1 as illustrated in the schematic block diagrams of FIGS. 1 and 2 may be implemented on a power amplifier die.

In the embodiment illustrated in FIG. 1 the attenuation of the active attenuator 3 can be modified by an attenuation bias current boosted by the transient compensation current Icomp generated by the transient compensation current generator during a transmission burst of the power amplification apparatus 1. The transmission burst can comprise a preamble for setting a level of modulation followed by a payload for data transmission.

The open loop transient gain compensation circuit 3 of the power amplification apparatus 1 can be adapted to compensate the transient turn-on gain variation of the power amplifier stage 2 with the transient compensation current Icomp within the initial 1 msec of the transmission burst of said power amplification apparatus 1.

The power amplification apparatus 1 as illustrated in the schematic block diagrams of FIGS. 1 and 2 forms part of a wireless communication device. The wireless communication device can comprise an antenna configured to transmit an amplified radio frequency signal. The power amplification apparatus 1 as illustrated in the embodiments of FIGS. 1 and 2 is configured to provide the amplified radio frequency signal to the antenna of the wireless communication device.

FIG. 3 shows a flowchart for illustrating a possible exemplary embodiment of a method for compensating a transient turn-on gain variation of a power amplifier stage according to a further aspect.

The method of compensating a transient turn-on gain variation of a power amplifier stage can be used when amplifying a signal such as an RF signal received from an attenuator or received from a variable gain amplifier.

In the illustrated embodiment of FIG. 3 the method for compensating a transient turn-on gain variation of a power amplifier stage comprises two main steps.

In a first step S1, transient compensation current Icomp is generated when turning-on the power amplifier stage.

In a further step S2, generated transient compensation current Icomp is added to a bias current Ibias. The electrical bias current can be supplied to the attenuator ATT to modify its attenuation or can be supplied to the variable gain amplifier VGA to modify its gain.

In a possible embodiment the transient turn-on gain variation of the power amplifier stage is compensated by the generated transient compensation current Icomp within the initial 1 msec of a transmission burst. This transmission burst can comprise a preamble used for setting a level of modulation followed by a payload used for data transmission.

The method for compensating a transient turn-on gain variation of the power amplifier stage is provided to counteract any power amplifier turn-on transient behavior. This ultimately improves error vector magnitude EVM for short and long transmission bursts. By applying the compensating gain function to an input active attenuator as illustrated in FIG. 1 or to variable gain amplifier 6 as illustrated in FIG. 2 it is possible to achieve a remarkable insensitivity to supply voltage changes, power amplifier temperature variations and burst length variations. The applied gain compensation function is relatively consistent across variations of different ambient conditions. The power amplifier stage 2 can also comprise a multi-mode power amplifier stage where an optimum gain compensation function does also vary in the power amplification apparatus 1 and its power amplifier stages 2 switches to different operation modes. With the method according to embodiments it is possible to supply a customized optimum gain compensation function in each operation mode as required.

Using the method according to embodiments, transient gain corrections may be achieved by applying an open loop gain correction with a programmable amplitude and time constant. This gain correction can be applied during a pulse and may be triggered by a power amplifier (PA) transmit enable control signal. The transient gain impairment is dominated by a single time constant. This means that a simple RC circuit can be used to generate a required gain compensation signal. For maximum flexibility and to reduce development time, that amplitude and time constant can be made programmable via an integrated controller of the power amplification apparatus 1.

The RC current transient output is the applied in the form of a bias current boost to an active attenuator 3 or to an active variable gain amplifier 6. In a possible implementation, the attenuation of the attenuator 3 or the gain of the variable gain amplifier 6 can be modified within the first 1 msec of a transmission burst.

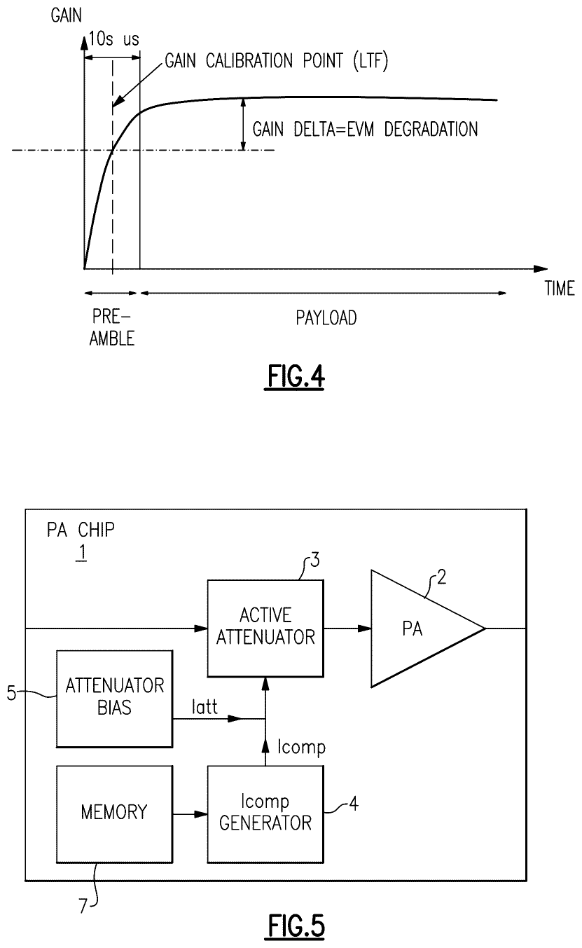

FIG. 4 illustrates the gain G over time t during a burst comprising a preamble and payload. The power amplifier switch on/turn on transients can still be present at a gain calibration point (LTF). In a conventional apparatus if there exists a discrepancy between the calibrated gain and the payload gain, distortion may result. The transient compensation current Icomp provided by the open loop transient gain compensation circuit 4 can compensate the power amplifier gain turn-on transient with an open loop generated transient bias current added to the bias current provided by the bias current source 5.

FIG. 5 illustrates a possible embodiment of a power amplification apparatus 1 implemented on a corresponding chip. In this illustrated embodiment of FIG. 5, the open loop transient gain compensation circuit 4 comprises a transient compensation current generator adapted to generate the transient compensation current Icomp added to the bias current received from the bias current source 5. In the illustrated embodiment of FIG. 5, the power amplification apparatus 1 comprises a memory circuit 7.

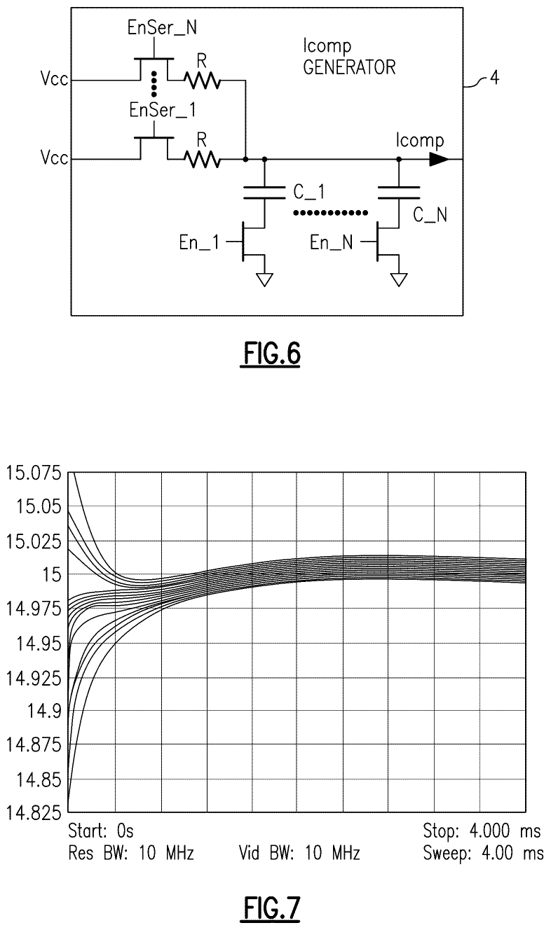

The transient compensation current generator of the open loop transient gain compensation circuit 4 can be implemented such as illustrated in FIG. 6. In the implementation shown in FIG. 6 the transient compensation current generator comprises a bank of capacitors C controlled according to settings of at least one register of the memory circuit 7 connected to the transient compensation current generator of the open loop transient gain compensation circuit 4 as shown in FIG. 5.

The transient compensation current generator the open loop transient gain compensation circuit 4 is adapted to output transient currents with a single RC-time constant. This current can be added to the bias current generated by the bias current source 5 and supplied to the attenuator 3 as shown in FIG. 5.

The transient compensation current Icomp can be varied using several registers of the memory circuit 7. The diagram illustrated in FIG. 7 illustrates that the measured power amplifier gain and the compensation current is varied using several registers. A register with 4 bits can comprise 16 different settings. In the example illustrated in FIG. 7, the optimal setting has been found at the register setting of “0111”.

FIG. 8 illustrates the error vector magnitude EVM without transient turn-on correction. As may be gathered from FIG. 8, at the beginning of the burst, i.e. near the training period, the EVM is less than-45 dB but the error vector magnitude EVM quickly degrades to −35 dB during the data burst.

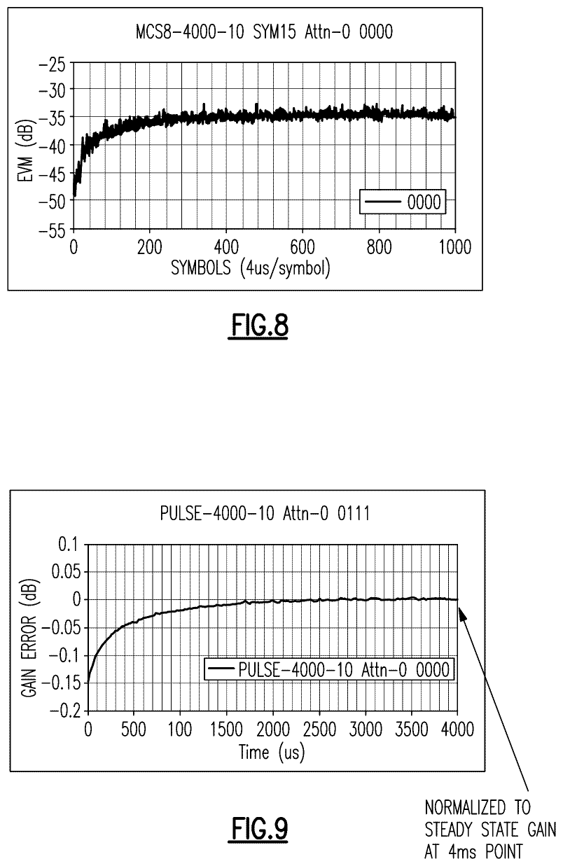

As can be seen in FIG. 9, the power amplifier gain variation over time indicates why the error vector magnitude EVM has degraded. At the beginning of the burst, the power amplifier gain is about 0.15 dB lower than it is towards the end of the burst. FIG. 9 illustrates a gain error without transient turn-on correction. FIGS. 8 and 9 illustrate a technical problem. The gain variation as illustrated in FIG. 9 is responsible for about 10 dB degradation in the error vector magnitude EVM between the beginning of the burst and the end of the burst as illustrated in FIG. 8. The gain is well controlled in the period between 2 msec to 4 msec due to a correct operation of a thermal feedback gain control mechanism. Accordingly, most of the EVM degradation is due to the transient turn-on gain issue as discussed above.

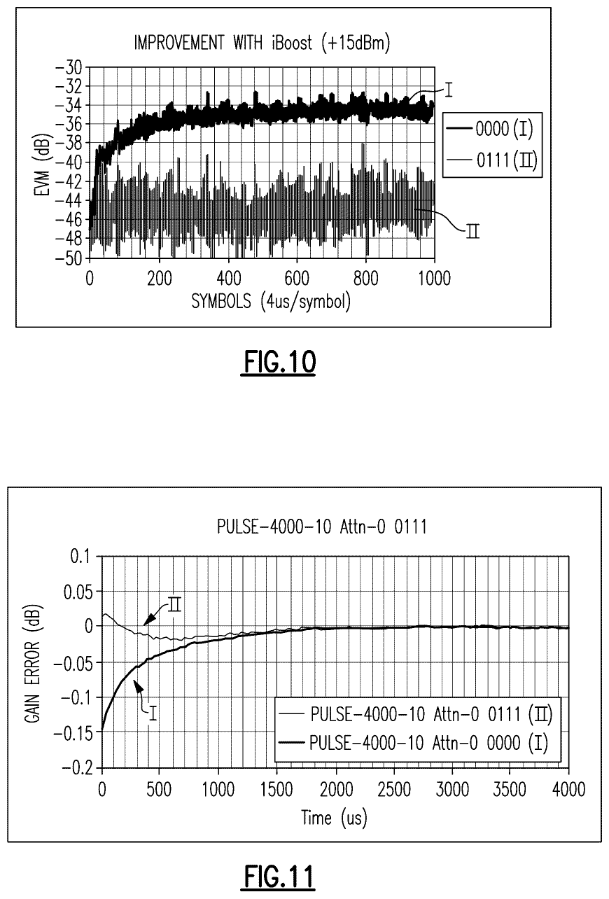

FIGS. 10 and 11 illustrate the effect of applying transient compensation current Icomp to an attenuator ATT or variable gain amplifier VGA to correct the turn-on transient of the power amplifier.

FIG. 10 illustrates the error vector magnitude EVM without transient turn-on correction (curve I) and with turn-on correction (curve II) according to some embodiments.

FIG. 11 illustrates the gain without transient turn-on correction (curve I) and with transient turn-on correction. Curve I in FIG. 11 illustrates a gain over time without gain compensation according to some embodiments. Curve II in FIG. II illustrates the gain over time applying the gain compensation implemented according to some embodiments.

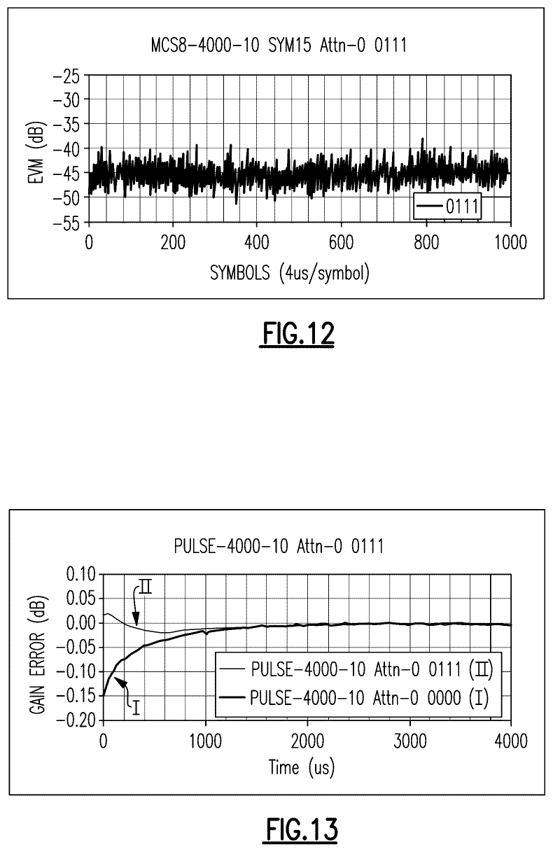

FIGS. 12 to 19 illustrate an insensitivity of the compensation method to supply voltage, burst length and duty cycle. A single RC-time constant can be applied across all operating conditions which further simplifies the circuit implementation.

FIG. 12 illustrates the error vector magnitude EVM with applied transient turn-on correction.

FIG. 13 illustrates the gain with and without transient correction. Curve I illustrates the gain over time without applying the gain compensation according to some embodiments. Curve II illustrates the gain error over time when applying the gain compensation using the method.

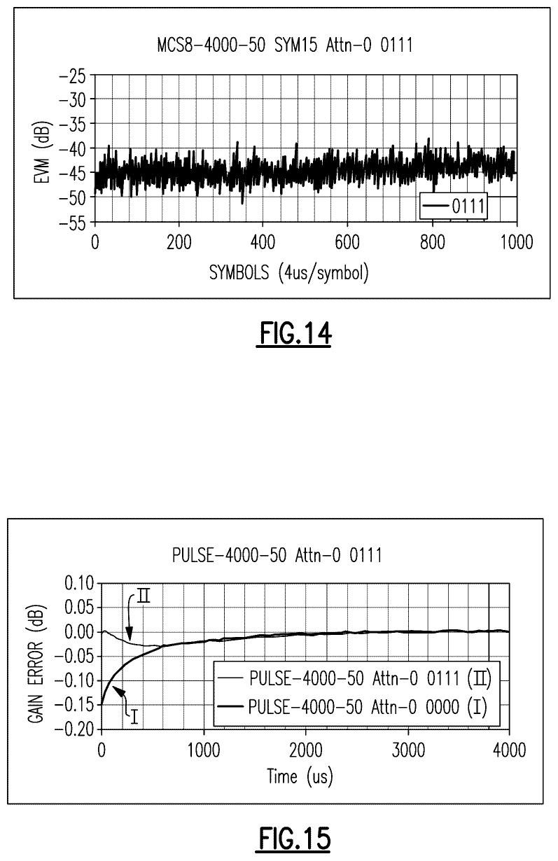

FIG. 12 illustrates, the error vector magnitude EVM during a 4 msec burst with a 10% duty cycle whereas FIG. 14 illustrates the error vector magnitude EVM with transient turn-on correction for a 4 msec burst with a 50% duty cycle.

FIG. 15 illustrates the corresponding gain over time with and without transient turn-on correction. Curve I of FIG. 15 illustrates the gain over time without gain compensation. Curve II of FIG. 15 illustrates the gain error over time when applying the gain compensation using the method according to some embodiments for a 50% duty cycle burst.

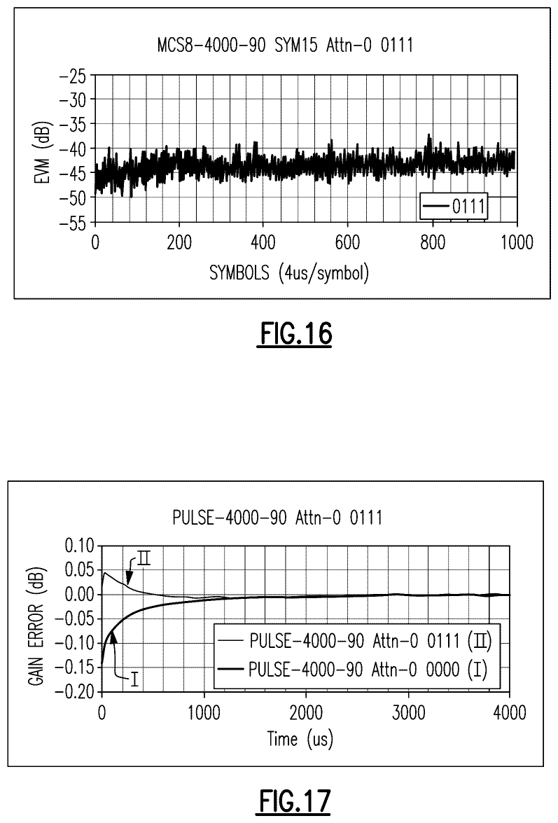

FIG. 16 illustrates the error vector magnitude EVM with transient turn-on correction for a 90% duty cycle.

FIG. 17 illustrates the corresponding gain over time with (curve II) and without (curve I) transient turn-on compensation.

The compensation scheme provided by the method according to some embodiments is almost insensitive to burst length variations of the transmission burst.

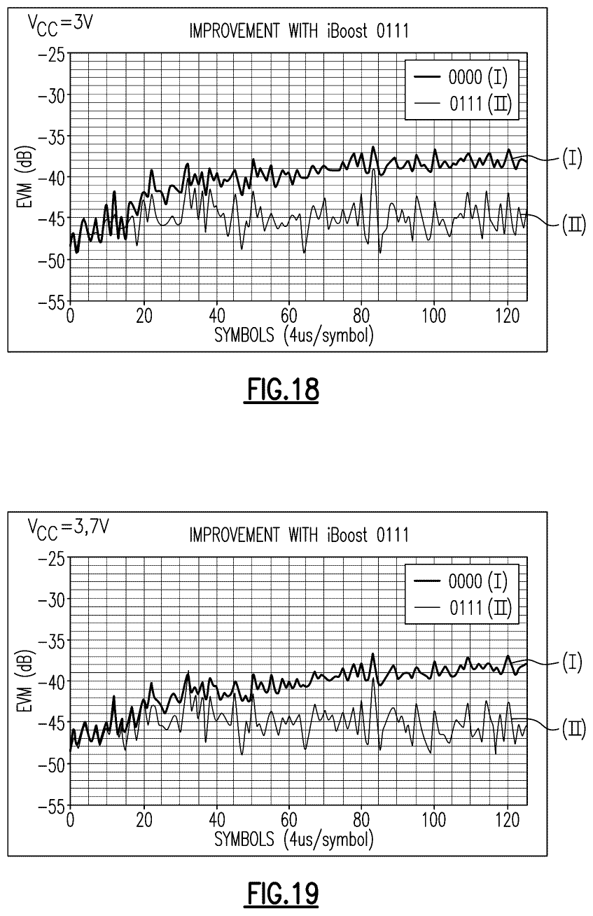

FIG. 18 illustrates the error vector magnitude EVM with and without gain correction for a supply voltage Vcc=3 V for a 50% duty cycle and a burst length of 300 msec. Curve I illustrates the error vector magnitude EVM without gain compensation whereas curve II illustrates the error vector magnitude EVM when applying gain compensation using the method. As can be seen the error vector magnitude EVM is significantly reduced when using the method according to some embodiments.

FIG. 19 illustrates the error vector magnitude EVM with and without gain correction for a different supply voltage of Vcc 3.7 V. Curve I illustrates the error vector magnitude EVM without gain compensation and curve II illustrates the error vector magnitude EVM with gain compensation.

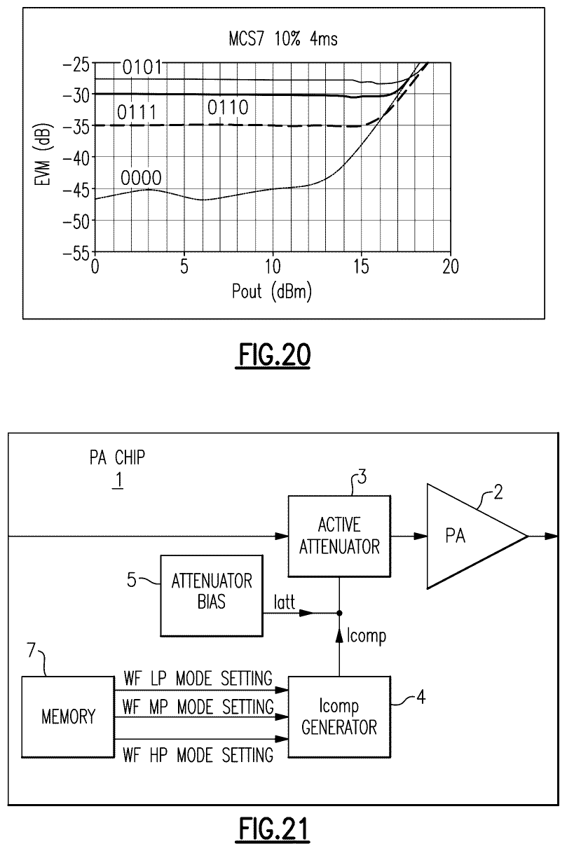

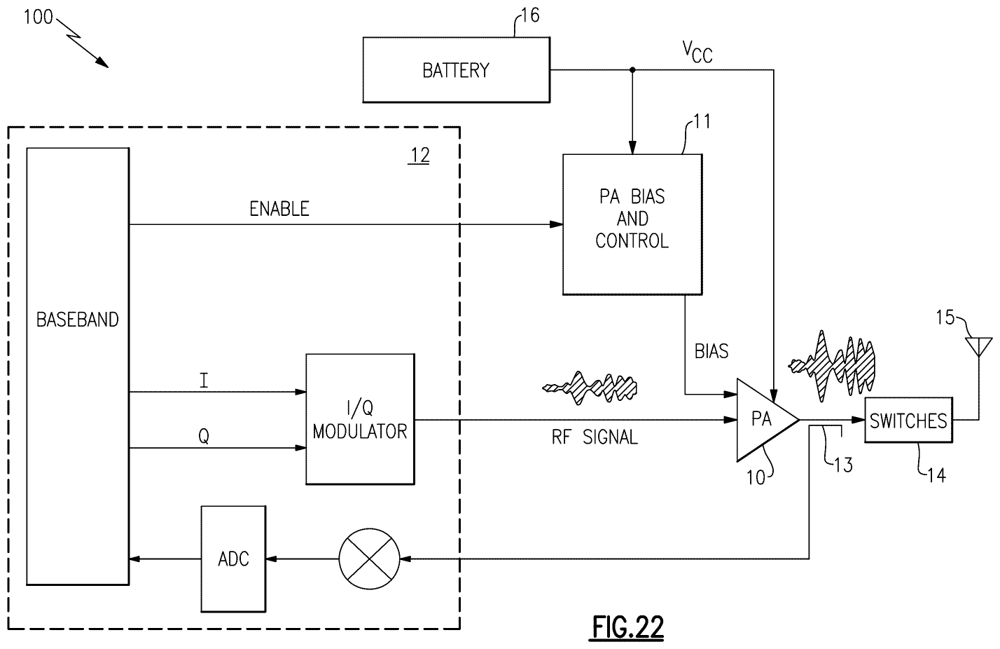

FIG. 20 shows a diagram of the error vector magnitude EVM over output power for different applied transient compensation currents Icomp. Different register settings can be applied for different modes. For instance the setting “0111” can be optimum for WF high power mode whereas the setting “0000” (transient compensation current Icomp is off) can be optimum for low power (LP) mode. As can be seen in FIG. 20, the setting “0111” (WF HP optimum setting) degrades the error vector magnitude EVM by 10 dB in comparison to setting “0000” where the transient compensation current is off. For multimode power amplifiers an optimum transient compensation current can be required for each WF operation mode. To compensate for a time constant dependence of an operation mode there is an associated mode dependent register setting that applies the optimum RC on a mode by mode basis as also illustrated in FIG. 21.

The method and apparatus according to embodiments provide a simple open loop gain correction scheme and is adapted to compensate power amplifier turn-on transient effects. The correction scheme can be applied to an input attenuator or to a variable gain amplifier as illustrated in FIGS. 1, 2. The gain correction scheme is thus isolated from the gain stages. Insensitivity to different operation conditions such as different supply voltages, different burst lengths, varying duty cycles or temperature changes may be achieved. The gain correction scheme according to some embodiments allows a simple circuit implementation to compensate different significant sources of non-linearity in the EVM.

The method further provides an identification of differences in power amplifier transient turn-on time constants versus WiFi mode settings and a mode dependent RC compensation current can be applied in each operation mode. This can be achieved by providing a set of registers that can store an optimum RC-time constant current to be supplied to the active attenuator 3 or to the variable gain amplifier 6. The gain correction scheme provides an excellent EVM performance in different operation modes, in particular WiFi modes, and the power amplification apparatus 1 can be realized with a compact and cost effective footprint.

FIG. 22 illustrates a schematic diagram of an exemplary electronic system such as a wireless communication device 100 comprising different components including a power amplifier 10 comprising power amplification apparatus 1 according to the first aspect. As illustrated, the wireless communication device 100 includes a power amplifier bias and control circuit 11, a transceiver 12, a directional coupler 13, a switch module 14, an antenna 15 and a battery 16.

The illustrated transceiver 12 can comprise a baseband signal processor, a mixer, an analog-to-digital converter ADC. In the illustrated application circuit, the baseband signal processor of the transceiver 12 can generate an I-signal and a Q-signal which can be used to represent a sinusoidal wave or a signal of a desired amplitude, frequency and phase. For example, the I-signal can represent an inphase component of the sinusoidal wave and the Q signal can represent a quadrature component of the sinusoidal wave, which can be an equivalent representation of the sinusoidal wave. In certain implementations I and Q signals can be provided to the IQ modulator of the transceiver 12 in a digital format. The baseband processor can be any suitable processor configured to process a baseband signal. For instance, the baseband processor can include a digital signal processor, a microprocessor, a programmable core, or any combination thereof. Moreover, in some embodiments, two or more baseband processors can be included in the wireless communication device 100.

The IQ modulator of the transceiver 12 can be configured to receive the I and Q signals from the baseband processor and to process the I and Q signals to generate an RF signal. For example the IQ modulator can include digital-to-analog converter DACs configured to convert the I and Q signals into an analog format, mixers for up-converting the I and Q signals to radio frequency, and a signal combiner for combining the up-converted I and Q signals into an RF signal suitable for amplification by the power amplifier 10 comprising the power amplification apparatus 1. In certain implementations, the IQ modulator may include one or more filters configured to filter frequency content of the signals processed therein.

The power amplifier bias and control circuit 11 can receive an enable signal ENABLE from the baseband processor and the battery or power high voltage Vcc from the battery 16. The power amplifier bias and control circuit 11 can generate a bias signal for the power amplifier 10 in response to the received enable signal. The power amplifier bias and control circuit 11 can also include circuitry configured to perform dynamic error vector magnitude (DEVM) compensation in accordance with any of the principles and advantages discussed herein. For instance, the bias and control circuit 11 can compensate changes in the gain of the power amplifier 10 over temperature during a relatively long burst. The bias and control circuit 11 may include also a temperature compensation circuit.

The directional coupler 13 can be positioned between the output of the power amplifier 10 and the input of the switch module 14, thereby allowing an output power measurement of the power amplifier 10 that does not include insertion loss of the switch module 14. The directional coupler 13 can be positioned at a different point in the wireless communication device 100 in some other instances. The output signal from the directional coupler 13 can be provided to the mixer of the transceiver 12 which can multiply the sensed output signal by a reference signal of a controlled frequency so as to downshift the frequency content of the sensed output signal to generate a downshifted signal. The downshifted signal can be provided to the analog-to-digital converter ADC of the transceiver 12 which converts the downshifted signal to a digital format suitable for processing by the baseband processor of the transceiver 12. By including the feedback path between the output of the power amplifier 10 and the baseband processor, the baseband processor can be configured to dynamically adjust the I and Q signals to optimize the operation of the electronic system 100. For example, configuring the wireless communication device 100 in this manner can aid in controlling the power added efficiency PAE and/or linearity of the power amplifier 10 comprising the power amplification apparatus 1 according to some embodiments.

While certain embodiments have been described, these embodiments have been presented by way of example only, and are not intended to limit the scope of the disclosure. Indeed, novel methods, apparatuses and systems described herein may be embodied in a variety of other forms. Furthermore, various emissions, substitutions and changes in the form of the methods, apparatus and systems described herein may be made without departing from the spirit of the disclosure. For example, circuit blocks described herein may be deleted, moved, added, subdivided, combined and/or modified. Each of the circuit blocks may be implemented and varied in a variety of different ways. The accompanying claims and their equivalents are intended to cover any such forms or modifications and would fall within the scope and spirit of the disclosure.

1. A power amplification apparatus comprising:
a power amplifier stage configured to amplify a signal received from an attenuator or from a variable gain amplifier of the power amplification apparatus with an amplifier gain; and
an open loop transient gain compensation circuit configured to compensate a transient turn-on gain variation of the power amplifier stage with a transient compensation current added to a bias current supplied to the attenuator or supplied to the variable gain amplifier.

2. The power amplification apparatus of claim 1 wherein the open loop transient gain compensation circuit includes a transient compensation current generator configured to generate the transient compensation current.

3. The power amplification apparatus of claim 2 wherein the transient compensation current generator of the open loop transient gain compensation circuit includes a memory circuit with a number of registers and a bank of capacitors controlled according to settings of at least one register of the memory circuit.

4. The power amplification apparatus of claim 2 wherein the transient compensation current generator of the open loop transient gain compensation circuit is adapted to generate a transient compensation current with a predefined RC-time constant.

5. The power amplification apparatus of claim 4 wherein a current amplitude and an RC-time constant of the transient compensation current are programmable via an integrated controller of the power amplification apparatus.

6. The power amplification apparatus of claim 3 wherein the memory circuit includes a set of registers having settings adapted to select a transient compensation current with an associated RC-time constant to be added to the bias current depending on an operation mode selected from a number of operation modes.

7. The power amplification apparatus of claim 6 wherein the operation mode includes a WiFi power mode.

8. The power amplification apparatus of claim 1 wherein the power amplifier stage and the open loop transient gain compensation circuit are implemented on a power amplifier die.

9. The power amplification apparatus of claim 2 wherein an attenuation of the attenuator is modified by an attenuation bias current boosted by the transient compensation current generated by said transient compensation current generator during a transmission burst of the power amplification apparatus.

10. The power amplification apparatus of claim 9 wherein the transmission burst includes a preamble for setting a level of modulation followed by a payload for data transmission.

11. The power amplification apparatus of claim 9 wherein the open loop transient gain compensation circuit is adapted to compensate the transient turn-on gain variation of the power amplifier stage with the transient compensation current within an initial first millisecond of the transmission burst.

12. A wireless communication device comprising:
an antenna configured to transmit an amplified radio frequency signal; and
a power amplification apparatus configured to provide the amplified radio frequency signal to the antenna, the power amplification apparatus including a power amplifier stage adapted to amplify a signal received from an attenuator or received from a variable gain amplifier of the power amplification apparatus with an amplifier gain, and an open loop transient gain compensation circuit configured to compensate a transient turn-on gain variation of the power amplifier stage with a transient compensation current added to a bias current supplied to the attenuator or supplied to the variable gain amplifier.

13. The wireless communication device of claim 12 wherein the open loop transient gain compensation circuit includes a transient compensation current generator configured to generate the transient compensation current.

14. The wireless communication device of claim 13 wherein the transient compensation current generator of the open loop transient gain compensation circuit includes a memory circuit with a number of registers and a bank of capacitors controlled according to settings of at least one register of the memory circuit.

15. The wireless communication device of claim 13 wherein the transient compensation current generator of the open loop transient gain compensation circuit is configured to generate a transient compensation current with a predefined RC-time constant.

16. The wireless communication device of claim 15 wherein a current amplitude and the predefined RC-time constant of the transient compensation current are programmable via an integrated controller of the power amplification apparatus.

17. The wireless communication device of claim 14 wherein the memory circuit includes a set of registers having settings adapted to select a transient compensation current with an associated RC-time constant to be added to the bias current depending on an operation mode selected from a number of operation modes.

18. A method of compensating a transient turn-on gain variation of a power amplifier stage used for amplifying a signal received from an attenuator or from a variable gain amplifier, the method comprising:
generating a transient compensation current when turning-on the power amplifier stage; and
adding the generated transient compensation current to a bias current supplied to the attenuator to modify its attenuation or supplied to the variable gain amplifier to modify its gain.

19. The method according to claim 18 wherein the transient turn-on gain variation of the power amplifier stage is compensated by the generated transient compensation current within an initial first millisecond of a transmission burst.

20. The method according to claim 19 wherein the transmission burst includes a preamble used for setting a level of modulation followed by a payload used for data transmission.
